(19) United States
(12) Patent Application Publication
(10) Pub. No.: US 2002/0192369 A1
(43) Pub. Date: Dec. 19, 2002

(54) Vapor deposition method and apparatus

(76) Inventors: Masahiro Morimoto, Narita-shi (JP); Hiroyuki Makizaki, Narita-shi (JP); Mamiko Miyanaga, Narita-shi (JP); Toshihiko Nishiyama, Narita-shi (JP)

Correspondence Address: Patent Counsel, Applied Materials, Inc., P.O. Box 450-A, Santa Clara, CA, 95052, US

(21) Appl. No.: 10/003,699

(22) Filed: Oct. 23, 2001

(30) Foreign Application Priority Data
Oct. 24, 2000 (JP) P2000-324271

(51) Int. Cl. C23C 16/00

(52) U.S. Cl. 427/248.1; 118/715; 118/712

(57) ABSTRACT

It is an object of the present invention to provide a vapor deposition method and apparatus which can supply gases onto a substrate fully stably with a favorable reproducibility, thus making it possible to reliably form a film having a favorable characteristic onto the substrate. A CVD apparatus 1 is one in which gas supply sources 31 to 34 are connected to a chamber 2 by way of gas supply pipes 51 to 54 equipped with MFCs 41 to 44 and valves 56 to 59. Also, bypass lines 71 to 74 joined to an exhaust pipe 4 are connected to parts 61 to 64 of the gas supply pipes 51 to 54. The bypass lines 71 to 74 are provided with valves 76 to 79. When the valves 76 to 79 and the valves 56 to 59 are opened/closed alternately from each other, the flow paths for each material gas can be switched over. The vapor deposition method in accordance with the present invention stabilizes the respective flow rates of material gases by such a valve operation, and then introduces these gases into the chamber 2.

### BACKGROUND OF THE INVENTION

1. Field of the Invention

The present invention relates to a vapor deposition method and apparatus; and, more specifically, to a vapor deposition method and apparatus for depositing a predetermined compound onto a substrate.

2. Related Background Art

Vapor deposition methods and apparatus such as CVD method and PVD method have been widely in use for making semiconductor devices. In the CVD method in particular, in order to form a desirable material film on a substrate such as a semiconductor substrate, one or a plurality of kinds of reactant gases are supplied as a material onto the substrate accommodated in a chamber. In this case, in order to obtain a desirable film quality, film thickness, and the like, it is necessary to adjust flow rates at which material gases are supplied, partial gas pressures, and the like in view of properties of the substrate and the like. The film quality (film characteristic) may be adversely affected depending on whether the adjustment is successful or not.

For example, in a nucleation step in a so-called W-CVD process for forming a metal layer made of tungsten (W) as a metal wiring layer on a substrate, WF₆ and SiH₄ gases have been in use in general, which are supplied onto the substrate while their flow rates are being adjusted by a mass flow controller (MFC).

### SUMMARY OF THE INVENTION

The inventors specifically studied such a nucleation step and its subsequent step of forming a tungsten film and, as a result, have found out that there are cases where (1) bumps occur on a nucleation film (seed layer) formed by the nucleation step, and (2) volcanoes occur due to the fact that the base layer is attacked by active species of fluorine. In these cases, there is a fear of tungsten insufficiently depositing and growing on the nucleation film, or the resulting tungsten film failing to have desirable electric characteristics.

The occurrence of such a phenomenon tends to depend on the order of supply of reactant gases. Specifically, it has been found that bumps are likely to occur when SiH₄ gas is supplied earlier than WF₆ gas, whereas volcanoes are likely to occur when WF₆ gas is supplied earlier than SiH₄ gas.

For this matter, the inventors noticed a certain extent of improvement by variously adjusting, in an early stage of supplying reactant gases, amounts of supply through the MFC and intervals (i.e., supply timings) at which individual gases were supplied. As a result of further studies, however, it has been found in this method that the response of flow rate adjustment and the like in the early stage of supplying reactant gases may be unstable whereas short- or long-term temporal fluctuations can occur after the adjustment is once made. As a consequence, it becomes harder to obtain a nucleation film having favorable characteristics and, therefore, a metal wiring layer.

In view of such circumstances, it is an object of the present invention to provide a vapor deposition method and apparatus which can supply gases onto a substrate fully stably with a favorable reproducibility in the early stage of supplying in particular, thus making it possible to reliably form a film having a favorable characteristic onto the substrate.

For overcoming the above-mentioned problems, the inventors further carried out studies and, as a result, have found:

(1) that so-called overshoot, in which the internal pressure of the chamber becomes higher than a predetermined pressure, is likely to occur in the early stage of supplying material gases;

(2) that one of the causes for the above is presumed to be an influence of a residual gas remaining in supply pipes for material gases in the early stage of supplying the material gases, e.g., the residual gas on the chamber side of flow-rate adjusting means such as MFC in particular;

(3) that, though the MFC is capable of precisely controlling the flow rate, it takes a considerable time for the flow rate to become stable after material gases flow out; and

(4) that the time required for the flow rate to become stable tends to vary among different kinds of reactant gases though dependable on the MFC and the like in use. Based on these findings, the present invention has been achieved.

Namely, the vapor deposition method in accordance with the present invention is a method comprising the step of supplying one or more kinds of material gases into a chamber accommodating a substrate therein from one or more gas sources containing the respective material gases, so as to deposit a predetermined compound onto the substrate; wherein the material gases are supplied from the respective gas sources to the outside of the chamber (e.g., to an exhaust system); and wherein, after a lapse of respective predetermined periods of time corresponding to the kinds of material gases, switching is made so as to supply the material gases into the chamber from the respective gas sources.

In thus constructed vapor deposition method, each material gas is initially supplied to the outside of the chamber, e.g., to the exhaust system, before being supplied into the chamber. At that time, the respective flow rates of material gases flowing out of gas sources fluctuate for a certain period of time depending on performances of the above-mentioned flow-rate adjusting means such as MFC, chamber form size, kinds of material gases, and the like, and can become stable at flow rate values within a substantially constant range thereafter. The gases are supplied to the outside of the chamber for a predetermined period of time until their flow rates become stable as such, and then are supplied into the chamber. As a consequence, each material gas is supplied onto the substrate at a desirable stable flow rate, whereby a predetermined compound is deposited due to reactions among the material gases.

Here, the time required for the flow rate of each material gas to become constant maybe determined with respect to various film-forming conditions and instrument conditions such as kinds of chambers and flow-rate adjusting means in use before forming a film onto a substrate, whereby the above-mentioned “predetermined period of time” can be set as “time” corresponding to the film-forming condition, instrument condition, and kind of material gas in actual film forming. In a trial prior to such film forming, each material gas may be supplied into the chamber from the beginning, so that the above-mentioned time can be determined as the time required for the pressure within the chamber to become stable. The guideline for “stability” of the flow rate and chamber internal pressure can appropriately be set according to the process and the like, for example, as a predetermined range of fluctuation (e.g., a range based on a confidence interval with reference to a standard deviation) with respect to a time average value of flow rate.

In another aspect, the vapor deposition method in accordance with the present invention is a method comprising the step of supplying one or more kinds of material gases into a chamber accommodating a substrate therein from one or more gas sources containing the respective material gases, so as to deposit a predetermined compound onto the substrate; wherein the material gases are supplied from the respective gas sources to the outside of the chamber; and wherein, after a flow rate of the material gases from the gas sources or a ratio of fluctuation thereof attains a value within a predetermined range, switching is made so as to supply the material gases into the chamber from the respective gas sources.

Consequently, as in the manner mentioned above, each material gas is supplied onto the substrate by a desirable stable flow rate, whereby a predetermined compound is deposited onto the substrate due to reactions among the material gases. Also, in this case, the stability of each material gas can substantially be determined according to the actual flow rate fluctuation of each material gas, and then switching is made so as to supply each material gas into the chamber instead of the outside, whereby more reliable operations can be carried out.

Preferably, a first gas including a compound containing a tungsten atom and a second gas including a compound containing a silicon atom are used as the one or more kinds of material gases, the first gas is supplied into the chamber before the second gas is supplied into the chamber, and the second gas is supplied into the chamber after the first gas is supplied into the chamber.

In a process using such first gas (e.g., WF₆ gas) and second gas (e.g., SiH₄ gas), a nucleation film (seed layer) can be formed. As mentioned earlier, the stability in flow rate of material gases and the like tend to greatly influence the film quality when forming the nucleation film. Hence, employing the vapor deposition method in accordance with the present invention reliably makes it easier to obtain a desirable crystal condition or a nucleation film excellent in film characteristics.

The vapor deposition apparatus in accordance with the present invention is an apparatus for effectively carrying out the vapor deposition method of the present invention, so as to deposit a predetermined compound by supplying one or more kinds of material gases onto a substrate, the apparatus comprising (a) a chamber for accommodating the substrate; (b) one or more gas sources including the respective material gases; (c) one or more gas supply sections, connected to the chamber and the respective gas sources, having respective flow-rate adjusting sections for adjusting flow rates of the material gases; (d) one or more gas exhaust sections connected between the respective gas flow-rate adjusting sections in the gas supply sections and the chamber; and (e) one or more blocking sections capable of independently blocking the material gases from being supplied to the chamber and the respective gas exhaust sections.

As a consequence, each material gas supplied from its corresponding gas source can be blocked by its blocking section from reaching any of the chamber and the respective exhaust section or so as to reach one of them. More specifically, for example, in the case where the gas supply sections have respective gas supply pipes for supplying the material gases whereas the gas exhaust sections have respective gas exhaust pipes connected to the gas supply pipes, examples of blocking sections include opening/closing valves provided in the gas supply pipes and gas exhaust pipes, and switching valves disposed at junctions between the gas supply pipes and gas exhaust pipes. Using such blocking sections makes it possible to rapidly supply/stop gases, whereby the flow rate fluctuation at that time can be suppressed.

Since the gas exhaust sections are connected between the gas flow-rate adjusting sections and the chamber, the material gases will continuously circulate through the respective flow-rate adjusting sections if the opening/closing of the blocking sections and the like are controlled such that each material gas is continuously supplied to one of its corresponding gas exhaust section and the chamber. This can effectively carry out the vapor deposition method of the present invention by which the flow rate of each material gas is stabilized.

Also, it will be useful if the vapor deposition apparatus in accordance with the present invention is an apparatus for effectively carrying out the vapor deposition method of the present invention, so as to deposit a predetermined compound by supplying one or more kinds of material gases onto a substrate, the apparatus comprising a chamber for accommodating the substrate; one or more gas sources including the respective material gases; one or more gas supply sections, connected to the chamber and the respective gas sources, having respective flow-rate adjusting sections for adjusting flow rates of the material gases; one or more gas exhaust sections connected between the respective gas flow-rate adjusting sections in the gas supply sections and the chamber; and one or more flow-path switching sections for switching respective flow paths of the material gases such that the material gases are supplied to one of the chamber and the respective gas exhaust sections.

As a consequence, each material gas supplied from its corresponding gas source can be supplied to one of the chamber and its exhaust section by the respective flow-path switching section. Since the gas exhaust sections are connected between the gas flow-rate adjusting sections and the chamber, the material gases continuously circulate through the respective flow-rate adjusting sections, whereby the vapor deposition method of the present invention can be carried out effectively and more reliably when such flow-path switching sections are provided.

Preferably, the apparatus further comprises a control section, connected to the blocking sections or the flow-path switching sections, for controlling opening/closing of the blocking sections or the switching of the flow paths effected by the respective flow-path switching sections, so as to start supplying the material gases to the chamber according to respective times sent out from the gas supply sections. This makes it possible to start supplying each material gas to the chamber after the flow rate of each material gas has become stable at a predetermined flow rate value.

Preferably, the apparatus further comprises a control section, connected to the flow-rate adjusting sections and the blocking sections or flow-path switching sections, for controlling the opening/closing of the blocking sections or the switching of the flow paths, so as to start supplying the material gases to the chamber according to respective flow rate value signals acquired by the flow-rate adjusting sections. As a consequence, the material gases can be supplied to the chamber after it is verified by flow-rate value signals from the respective flow-rate adjusting sections that respective flow rates of the material gases have become stable at a predetermined flow rate value, whereby the flow rate fluctuation can be suppressed further reliably.

The present invention is quite suitable when the one or more kinds of material gases are a first gas including a compound containing a tungsten atom, and a second gas including a compound containing a silicon atom; whereas the one or more gas sources are a first gas source including a first gas, and a second gas source including a second gas.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1 is a diagram (partly sectional view) showing an outline of a preferred embodiment of vapor deposition apparatus in accordance with the present invention;

FIG. 2 is a timing chart showing operations of major parts of the CVD apparatus in a film forming process;

FIG. 3 is a graph showing the temporal change of WF₆ gas flow rate in Comparative Example 1;

FIG. 4 is a graph showing the temporal change of WF₆ gas flow rate in Example 1;

FIG. 5 is a graph showing the temporal change of chamber internal pressure in Comparative Example 1;

FIG. 6 is a graph showing the temporal change of chamber internal pressure in Example 1;

FIG. 7 is a graph showing temporal changes of WF₆ gas and SiH₄ gas concentrations in Example 1;

FIG. 8 is a graph showing temporal changes of WF₆ gas and SiH₄ gas concentrations in Example 2;

FIG. 9 is a graph showing the sheet resistance value of the semiconductor wafer of Comparative Example 1; and

FIG. 10 is a graph showing the sheet resistance value of the semiconductor wafer of Example 1.

### DESCRIPTION OF THE PREFERRED EMBODIMENTS

In the following, embodiments of the present invention will be explained in detail. Constituents identical to each other will be referred to with numerals or letters identical to each other without repeating their overlapping descriptions. Positional relationships such as upper, lower, left, and right will be based on those shown in the drawings unless otherwise specified. Ratios of dimensions in the drawings are not restricted to those depicted.

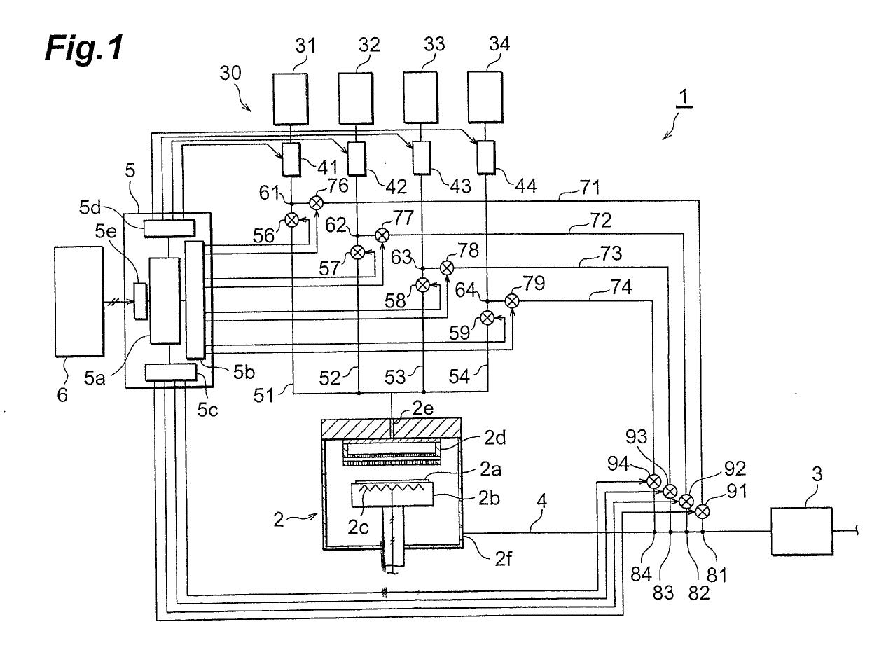

As mentioned above, FIG. 1 is a diagram (partly sectional view) showing an outline of a preferred embodiment of the vapor deposition apparatus in accordance with the present invention. The CVD apparatus 1 (vapor deposition apparatus) is one in which gas supply sources 31 to 34 (individual gas sources) are connected, by way of a gas supply section 30, to a chamber 2 for accommodating a semiconductor wafer 2a (substrate).

The chamber 2 has a susceptor 2b for mounting the semiconductor wafer 2a, a shower head 2d having a hollow substantially disc-like form is disposed above the susceptor 2b. The susceptor 2b is hermetically disposed in the chamber 2 by means of an O-ring, a metal seal, or the like, and is made vertically movable by means of a driving mechanism which is not depicted. As a consequence, the gap between the semiconductor wafer 2a and the shower head 2d is adjusted. Further, a heater 2c is built within the susceptor 2b, which heats the semiconductor wafer 2a to a desirable temperature.

A gas inlet 2e is formed in the upper portion of the chamber 2, so that the gases supplied from the gas supply section 30 are introduced from the gas inlet 2e into the chamber 2. The gases introduced into the chamber 2 from the gas inlet 2e are fully dispersed and mixed by the shower head 2d before flowing out toward the semiconductor wafer 2a. As a consequence, thus mixed plurality of kinds of gases is supplied onto the semiconductor wafer 2a. The wall face of the chamber 2 on its lower side is formed with an outlet 2f, to which a vacuum pump 3 is connected by way of an exhaust pipe 4. This reduces the pressure within the chamber 2.

The gas supply sources 31 to 34 include argon (Ar) gas, WF₆ gas, SiH₄ gas, and hydrogen (H₂) gas, respectively. The gas supply section 30 further comprises gas supply pipes 51 to 54, equipped with respective MFCs 41 to 44 (individual flow-rate adjusting sections) and respective valves 56 to 59 (individual blocking sections), having respective one ends connected to the gas supply sources 31 to 34. The other ends of the gas supply pipes 51 to 54 are joined together and connected to the chamber 2.

Connected to the gas supply pipes 51 to 54 at parts 61 to 64 between the MFCs 41 to 44 and the valves 56 to 59 are bypass lines (diverters) 71 to 74 having respective valves 76 to 79. The bypass lines 71 to 74 are connected to parts 81 to 84 in the above-mentioned exhaust pipe 4, respectively. Further provided near the parts 81 to 84 in the bypass lines 71 to 74 are valves for backflow prevention 91 to 94. Thus, the valves 76 to 79, 91 to 94, and bypass lines 71 to 74 constitute the gas exhaust sections.

When the opening/closing states of the valves 56 to 59 and those of the valves 76 to 79 or valves 91 to 94 are changed over therebetween, the respective flow paths of gases can be switched. Thus, these members constitute the flow-path switching sections. In this embodiment, the valve 93 is always open (though not restricted thereto).

Here, as the valves 56 to 59, 76 to 79, and 91 to 94, an air-operated valve (hereinafter referred to as “air valve”), which is driven by compressed air, is used, for example. More specifically, employed as each of the above-mentioned valves is preferably of so-called normally closed type which is closed when no air pressure is applied thereto by compressed air but is opened when the air pressure is applied thereto, or so-called normally open type which acts to the contrary. The valves 91 to 94 maybe check-valves as well.

The CVD apparatus 1 comprises a control section 5 having a CPU 5a, output interfaces 5b, 5c, 5d, and an input interface 5e. By way of the output interfaces 5b, 5c, the CPU 5a is connected to the valves 56 to 59 and the valves 76 to 79, and the valves 91 to 94, respectively, thereby independently controlling the opening/closing of the individual valves.

The CPU 5a is also connected to the MFCs 41 to 44 by way of the output interface 5d, and outputs flow rate signals for setting the respective flow rates of material gases flowing through the MFCs 41 to 44. Further connected to the control section 5 is an input device 6, by which a film-forming program including respective switching timings for the air valves and conditional setting values such as the respective flow rates of material gases is fed to the CPU 5a by way of the input interface 5e. When this film-forming program is executed, control operations such as the valve opening/closing and flow rate adjustment by the control section 5 are carried out according to a predetermined film-forming condition.

An example of the vapor deposition method in accordance with the present invention using thus configured CVD apparatus 1 will now be explained. First, the pressure within the chamber 2 is reduced by the vacuum pump 3. Under thus reduced pressure, the semiconductor wafer 2a is mounted on the susceptor 2b, and the semiconductor wafer 2a is heated to a predetermined temperature by way of the susceptor 2b .

Subsequently, according to an instruction signal from the control section 5, the valve 56 is opened while the valves 76, 91 are closed, whereby the Ar gas is introduced into the chamber 2 by way of the gas supply pipe 51. Similarly, the H₂ gas is introduced into the chamber 2 by way of the gas supply pipe 54.

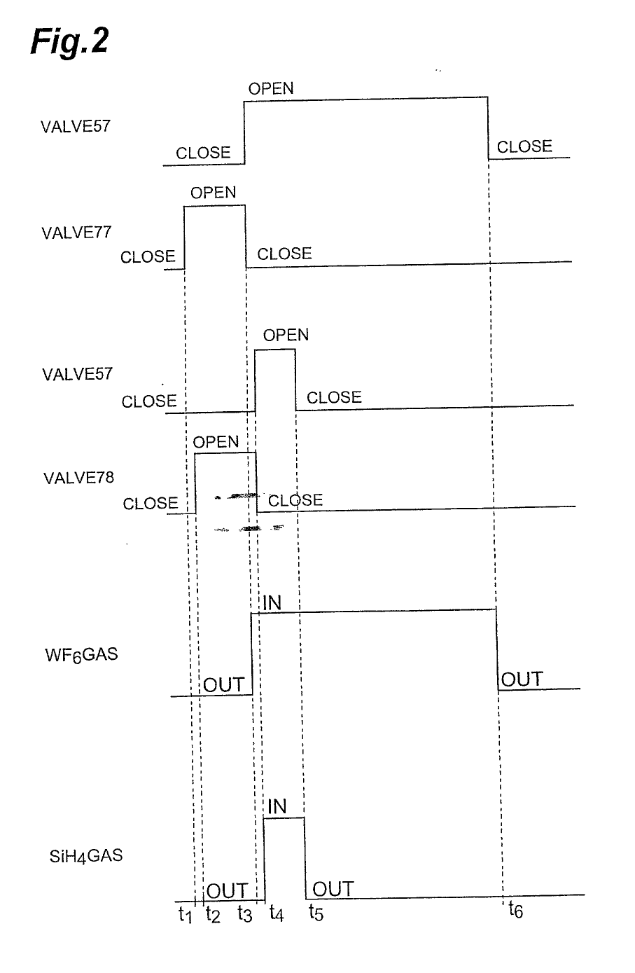

Then, after a predetermined pressure is attained within the chamber 2, a W nucleation film as a seed layer and a W film are successively formed in this order. Here, as mentioned above, FIG. 2 is a timing chart showing operations of major parts of the CVD apparatus 1 in this film-forming process. In this chart, “IN” indicates the state where the gases are supplied to the chamber 2, whereas “OUT” indicates the state where the gases flow into the exhaust pipe 4 via bypass lines.

First, at time t₁ in this case, the valve 57 is closed whereas the valves 77, 92 are opened, so that the WF₆ gas is caused to flow into the bypass line 72 by way of the MFC 42 and part 62, so as to circulate through the exhaust pipe 4. While flowing through such a flow path, the WF₆ gas is regulated by the MFC 42 so as to attain a predetermined stable flow rate preset by the flow rate signal outputted to the MFC 42 from the control section 5.

Subsequently, at time t₂, the valve 58 is closed whereas the valves 78, 93 are opened (the valve 93 being always open as mentioned above), so that the SiH₄ gas is caused to flow into the bypass line 73 by way of the MFC 43 and the part 63 so as to circulate through the exhaust pipe 4. While flowing through such a flow path, the SiH₄ gas is regulated by the MFC 43 so as to attain a predetermined stable flow rate preset by the flow rate signal outputted to the MFC 43 from the control section 5.

Then, at time t₃ when the flow rate of the WF₆ gas has become stable, the valves 77, 92 are closed whereas the valve 57 is opened. As a consequence, the flow path of the WF₆ gas is switched over, so that the WF₆ gas is introduced into the chamber 2 by way of the MFC 42, part 62, valve 57, and gas supply pipe 52. Though dependable on the gas flow rate and performances of MFC and the like, the time interval between t₁ and t₃ is preferably at least 5 seconds, more preferably 5 to 10 seconds. If the time interval is less than the lower limit mentioned above, the flow rate will tend to fail to become fully stable. If the time interval exceeds the upper limit mentioned above, by contrast, the amount of consumption of the material will tend to increase more than necessary.

Subsequently, at time t₄ when the flow rate of SiH₄ has become stable, the valve 78 is closed whereas the valve 58 is opened. As a consequence, the flow path of the SiH₄ gas is switched over, so that the SiH₄ is introduced into the chamber 2 by way of the MFC 43, part 63, valve 58, and gas supply pipe 53. Here, the time interval between t₂ and t₄ can be made similar to the time interval between t₁ and t₃. From that point in time, the forming of the W nucleation film is started.

Thereafter, at time t₅, the valve 58 is closed whereas the valve 78 is opened. As a consequence, the flow path of the SiH₄ gas is switched over, whereby the SiH₄ gas is caused to flow into the exhaust pipe 4 again by way of the branching part 63, valve 78, bypass line 73, and valve 93. Since the SiH₄ gas is thus stopped from being introduced into the chamber 2, the forming of the W nucleation film is terminated, whereby the W film is formed on the semiconductor wafer 2a thereafter. At that time, the amount of supply of the WF₆ gas into the chamber 2 may be changed by suitable means as appropriate. When the SiH₄ gas is stopped from being introduced into the chamber 2, the valve 58 may be closed alone while the valve 78 is kept closed. As a consequence, the SiH₄ gas is kept from flowing into the bypass line 73 at the same time when it is stopped from being introduced into the chamber 2, whereby the SiH₄ gas can be prevented from being wasted.

Then, at time t₆, the valve 57 is closed whereas the valves 77, 92 are opened. As a consequence, the flow path of the WF₆ gas is switched over, so that the WF₆ gas is caused to flow into the exhaust pipe 4 again by way of the branching part 62, valve 77, bypass line 72, and valve 92. This completes the forming of the W film, thereby yielding the semiconductor wafer 2a in which the W nucleation film and the W film are formed in succession. When stop forming the W film, the valve 57 may be closed while the valves 77, 92 are kept closed as in the above-mentioned case of SiH₄ gas. After forming the W film, the material gas within the chamber 2 is purged by Ar gas. Thereafter, the semiconductor wafer 2a is taken out of the chamber 2.

When forming the W nucleation film as a seed layer in thus configured CVD apparatus 1 and vapor deposition method of the present invention, each of the WF₆ gas and SiH₄ gas is initially caused to flow into the exhaust pipe 4 and then is introduced into the chamber 2 by switching over the flow path after the flow rate of each gas has become stable, whereby these gases are stably supplied onto the semiconductor wafer 2a. Therefore, a W nucleation film having a desirable composition and a favorable crystallinity can reliably be formed.

Also, since the opening/closing operations of the valves 57, 77 and valves 58, 78 are carried out individually, respective timings at which the WF₆ gas and SiH₄ gas are supplied into the chamber 2 can be controlled independently from each other. Hence, bumps, volcanoes, and the like can fully be restrained from occurring on the W nucleation film.

Each of the difference between times t₁ and t₃ and the difference between times t₂ and t₄ is preferably a period of time sufficient for making the material gas flow rate to become stable, and can be determined as appropriate in view of the gas pressure within the gas supply pipe, the response time of each MFC, and the like. Instead of determining the switchover timing between the valves 57, 58 and valves 77, 78 in terms of time, a method determining whether the flow rate is stabilized or not can also be used. Namely, while the flow rate value signal outputted from each MFC is monitored by the control section 5, for example, the valves 57, 58 and vales 77, 78 may automatically be switched over therebetween after it is determined that thus monitored signal has attained a value within a predetermined fluctuation range (e.g., a range based on a confidence interval with reference to a standard deviation) with respect to the time average value of the gas flow rate, so as to introduce the material gas into the chamber 2.

Since the optimal value of the difference between times t₃ and t₄ may vary depending on the supply length (pipe length or the like) of each gas or its pipe inner diameter, it is desirable that optimization be carried out as appropriate. Also, operations may be carried out manually instead of the opening/closing operations and control carried out by the control section 5.

As the parts 61 to 64 and 81 to 84, piping joints such as those with a T-shape using a metal seal can be used. Other members such as welded piping joints with a T-shape may also be used. Further, three-way valves may be provided at parts of such T-shaped joints and the like. In this case, the valves 56 to 59, 76 to 79 may be omitted as well. Also, the gas retention area formed within such a valve, i.e., so-called dead space, can be made smaller, whereby the fluctuation in gas flow rate, which may occur at the time of switching the gas flow paths, and its resulting pressure change within the chamber 2 can be suppressed.

For example, air valves of normally closed type may be used in any of the valves 56 to 59, 76 to 79, and the valves 91 to 94. The compressed air for air valves may be either instrumentation air or service air. Also, it may be the air stored in a bomb. Nitrogen gas from a high-pressure nitrogen gas cylinder is also preferable. Also, other electrically controllable opening/closing valves such as electromagnetic valves, various dampers, and the like may be used as the valves 56 to 59, 76 to 79, and 91 to 94.

Though the W nucleation film and W film are formed in succession by using the WF₆ gas and SiH₄ gas in the above-mentioned embodiment, the kinds of material gases, the number of kinds thereof, and the film materials are not restricted thereto. For example, when forming a silicon oxide (SiO₂ or SiOₓ) film by using TEOS (Tetra Ethyl Ortho Silicate) and ozone (O₃) gases as material gases, the CVD apparatus 1 and a method using the same can be employed favorably. The CVD apparatus 1 maybe a plasma CVD apparatus for carrying out plasma processing, such as a CVD apparatus of high-density plasma (HDP) type, for example.

### EXAMPLES

Specific examples in accordance with the present invention will now be explained, which will not restrict the present invention.

### Comparative Example 1

An apparatus based on a CVD apparatus (CENTURA (registered trademark); WxZ+ chamber) manufactured by Applied Materials, Inc. having a configuration similar to that of the CVD apparatus 1 shown in FIG. 1, was prepared (hereinafter referred to as “CVD apparatus 1” for convenience of explanation) . In order to carry out film forming by a method similar to the conventional vapor deposition method, the deposition was carried out in the following procedure different from the operations of the timing chart shown in FIG. 2 (i.e., the operations in the vapor deposition method in accordance with the present invention).

Namely, a semiconductor wafer (bare wafer) was accommodated within the chamber 2, the pressure therein was reduced to a predetermined pressure, and then Ar gas and H₂ gas were supplied into the chamber 2. After a predetermined pressure was attained within the chamber 2, WF₆ gas and SiH₄ gas were sent out from the gas supply sources 32 and 33, respectively, in a state where the valves 57, 77 and vales 58, 78 were closed. Thereafter, the valves 57 and 58 were opened, so as to supply the WF₆ gas and SiH₄ gas into the chamber 2, thereby forming a W nucleation film. Further, after the lapse of a predetermined period of time, the valve 58 was closed so as to stop supplying the SiH₄gas. Thereafter, a W film was formed for a predetermined period of time, whereby a semiconductor wafer in which the W nucleation film and W film were formed in succession was obtained.

The film-forming conditions at that time were as follows:

WF₆ gas flow rate: 30 sccm (at the time of forming the W nucleation film), 150 sccm (at the time of forming the W film)

SiH₄ gas flow rate: 15 sccm

Ar gas flow rate: 2800 sccm (at the time of forming the W nucleation film), 1200 sccm (at the time of forming the W film)

H₂ gas flow rate: 1000 sccm (at the time of forming the W nucleation film), 500 sccm (at the time of forming the W film)

Film-forming temperature: 405° C.

Here, the flow rate unit [sccm] refers to [cm³/min] (ditto in the following).

### Example 1

Using the CVD apparatus 1 employed in Comparative Example 1, a semiconductor wafer 2a in which the W nucleation film and W film were formed in succession was obtained in the same manner as Comparative Example 1 except that the valve opening/closing operations were carried out in conformity to the timing chart shown in FIG. 2 and that the WF₆ gas flow rate was 20 sccm at the time of forming the W nucleation film.

WF₆ Gas Flow Rate Measuring Test

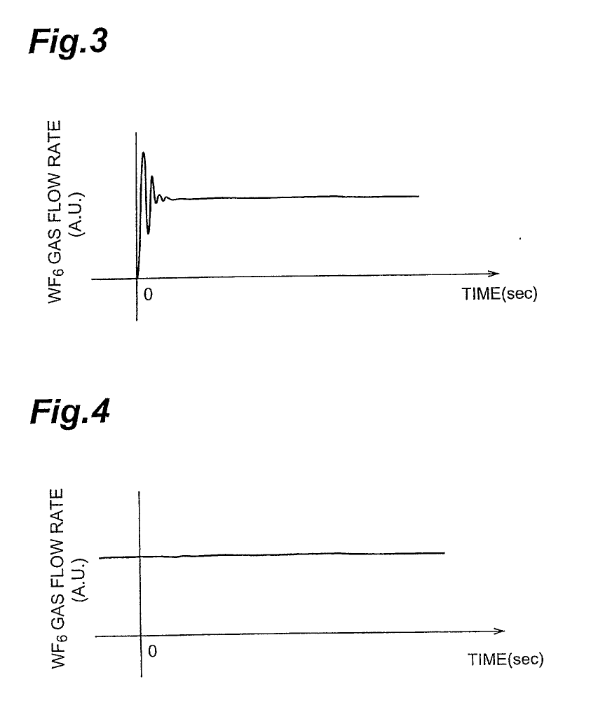

The WF₆ gas flow rate at the time when film forming was carried out was measured in Comparative Example 1 and Example 1. Here, the flow rate measuring position was at the position of MFC 42, whereas the output value of the MFC 42 was taken as the actually measured flow rate value. The results are shown in FIGS. 3 and 4. As mentioned above, FIGS. 3 and 4 are graphs showing temporal changes in WF₆ gas flow rate in Comparative Example 1 and Example 1, respectively.

In Comparative Example 1, as shown in FIG. 3, the flow rate of WF₆ gas was zero before opening the valve 57 (before zero in time axis), and rapidly increased when the valve 57 is opened. Thereafter, it fluctuated vibratingly before attaining a predetermined flow rate. This is presumed to be because of the fact that the flow rate control by the MFC 42 cannot sufficiently respond to the rapid flow of WF₆ gas started when the valve 57 is opened. Thus, it was verified that the method of Comparative Example 1 failed to stabilize the gas flow rate immediately after the gas was introduced into the chamber 2.

In Example 1, by contrast, fluctuations were hardly seen in the flow rate of WF₆ gas between before and after the WF₆ gas was introduced into the chamber 2 (before and after the zero point in the time axis) . This was seen to be a result of switching gas flow paths by changing the opening/closing of the valves 57 and 77 after the flow rate of WF₆ gas became stable, though the WF₆ gas had flowed at a desirable flow rate from the MFC 42 to the exhaust pipe 4 by way of the bypass line 72 before being introduced into the chamber 2. It was also verified that no fluctuations in flow rate occur upon operations for switching the valves.

Chamber Internal Pressure Measuring Test

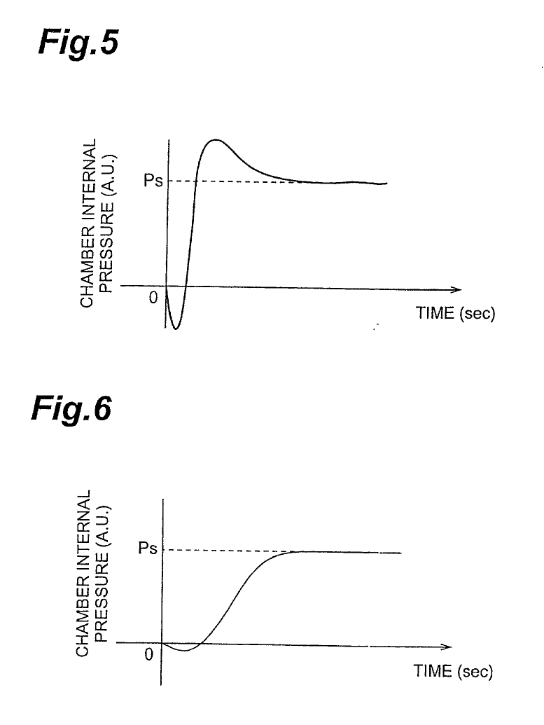

The pressure within the chamber 2 was measured when film forming was carried out in Comparative Example 1 and Example 1. Here, the output value from a pressure regulator (not depicted) provided in the chamber 2 was taken as the actually measured chamber internal pressure value. The results are shown in FIGS. 5 and 6. As mentioned above, FIGS. 5 and 6 are graphs showing temporal changes in the pressure within the chamber 2 in Comparative Example 1 and Example 1, respectively.

In Comparative Example 1, as shown in FIG. 5, the pressure within the chamber 2 once rapidly decreased immediately after the valve 57 was opened, and then rapidly increased to the contrary, thereby exceeding a set pressure value Pₛ (overshoot) . Thereafter, it gradually decreased before becoming stable at the set pressure value Pₛ. When the pressure within the chamber 2 overshoots as such, it tends to fail to sufficiently control the composition and evenness in film thickness of the film to be deposited or the deposition rate thereof.

In Example 1, by contrast, the pressure within the chamber 2 slightly decreased immediately after the valve 57 was opened, and then mildly increased to the set pressure value Pₛ without overshooting as shown in FIG. 6. Therefore, the superiority of the vapor deposition method in accordance with the present invention was verified.

### Example 2

A semiconductor wafer 2a in which a W nucleation film and a W film were formed in succession was obtained in the same manner as Example 1 except that valve operations were carried out such that the times t₃ and t₄ became the same point in time.

Test for Measuring Material Gas Concentration within Chamber

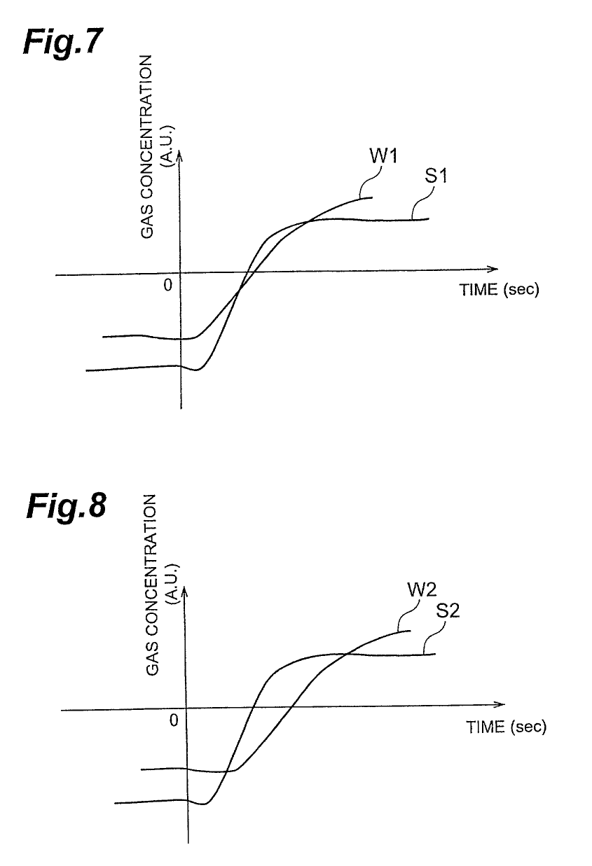

The concentrations of WF₆ gas and SiH₄ gas within the chamber 2 were measured when film-forming was carried out in Examples 1 and 2. At that time, the gas concentration measurement within the chamber 2 was carried out by measuring the increase in chamber internal pressure with a chart recorder. The results are shown in FIGS. 7 and 8. As mentioned above, FIGS. 7 and 8 are graphs showing temporal changes in WF₆ gas and SiH₄ gas concentrations in Examples 1 and 2, respectively. In these graphs, curves W1 and W2 show the results concerning the WF₆ gas, whereas curves S1 and S2 show the results concerning the SiH₄ gas.

As shown in FIGS. 7 and 8, it was clarified that fluctuations in concentration of each gas hardly occurred in each of Examples 1 and 2. In Example 1, the difference in concentration between the WF₆ gas and SiH₄ gas tended to become smaller than that in Example 2, and the consistency in rising times was favorable in particular.

Sheet Resistance Measuring Test 1

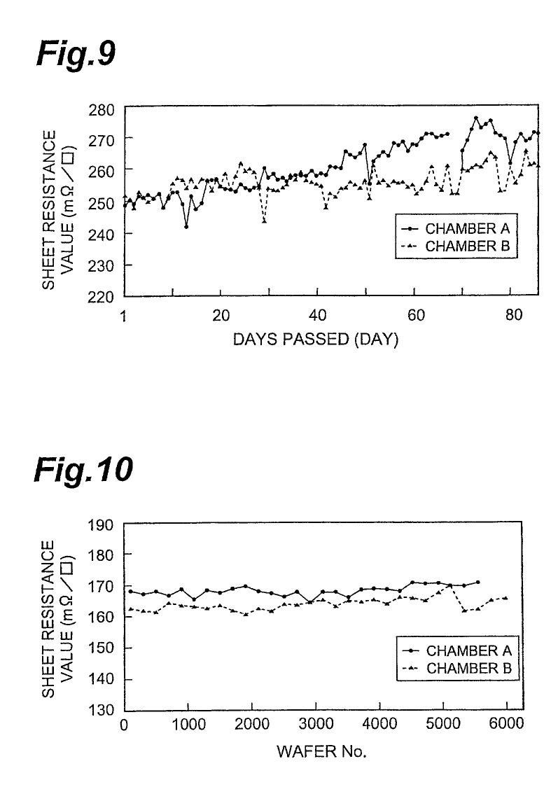

Sheet resistance values were measured in the semiconductor wafers 2a manufactured over a period of about 2.5 months after the MFCs were once adjusted by the methods of Comparative Example 1 and Example 1. FIG. 9 is a graph showing the sheet resistance values of semiconductor wafers obtained during this manufacturing campaign in Comparative Example 1. For film forming, two chambers were used, and the respective results in the chambers (chambers A, B) are shown together in FIG. 9.

As shown in FIG. 9, it was verified that the sheet resistance value tended to gradually increase as the number of campaign days passed. Also, it was seen that the sheet resistance value greatly fluctuated within the range of about 240 to 280 mΩ/□. On the other hand, it was seen that the difference in sheet resistance value between two chambers tended to increase. One of its causes is presumed to be the fluctuation in flow rate effected by MFCs. By contrast, such tendencies were not seen in the semiconductor wafer 2a of Example 1.

Sheet Resistance Measuring Test 2

According to the method of Example 1, 6,000 sheets of semiconductor wafers 2a (in which a W nucleation film and a W film were formed in succession) were manufactured, and their sheet resistance values were measured. The results are shown in FIG. 10. FIG. 10 is a graph showing sheet resistance values of the 6,000 sheets of semiconductor wafers 2a obtained by Example 1. For film forming, two chambers were used, and the respective results in the chambers (chambers A, B) are shown together in FIG. 10. Plots in the graph indicate central values per predetermined number of sheets.

As shown in FIG. 10, it was verified that the fluctuation in sheet resistance value was sufficiently suppressed, while the difference in sheet resistance value between the two chambers was substantially constant. Therefore, it was seen that electrically conductive films excellent in electric characteristics were obtained with a favorable reproducibility in accordance with the present invention when any of the chambers was used. Also, the ratio of fluctuation in so-called Run-to-Run sheet resistance value calculated from the results shown in FIG. 10 was ±2.6% and thus was favorable.

Yield Measuring Test

Film forming was carried out for 6,000 sheets of semiconductor wafers 2a in each of Comparative Example 1 and Example 1, and the number of non-defective products was counted also in view of specification values concerning characteristic values other than the sheet resistance value. Based on thus obtained results, the yield (non-defective product ratio) was determined. As a result, the yield in Example 1 was about 82%, whereas that of Comparative Example 1 was about 77%.

As mentioned earlier, Comparative Example 1 using the conventional CVD apparatus and method introduced material gases into the chamber by opening the gas supplying valves from the state where no material gases flow, thus failing to sufficiently regulate the composition of the W nucleation film in the early stage of film forming. By contrast, Example 1 using the CVD apparatus 1 and method in accordance with the present invention caused the WF₆ gas and SiH₄ gas to flow into the bypass lines 72, 73 beforehand so as to stabilize their flow rates, and then switched over the valves 57, 58 and the valves 77, 78 therebetween, thus being able to introduce both of the material gases into the chamber 2 at desirable flow rates. It is presumed that these result in achieving the improvement in yield. Thus, it has been verified that the present invention can improve the efficiency in production.

As explained in the foregoing, the vapor deposition method and apparatus in accordance with the present invention can supply gases onto a substrate sufficiently stably with a good reproducibility in the early stage of supplying in particular. As a consequence, films having favorable characteristics can reliably be formed on a substrate, which makes it possible to improve the efficiency in production.

From the invention thus described, it will be obvious that the embodiments of the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A vapor deposition method comprising the step of supplying one or more kinds of material gases into a chamber accommodating a substrate therein from one or more gas sources containing said respective material gases, so as to deposit a predetermined compound onto said substrate;
wherein said material gases are supplied from said respective gas sources to the outside of said chamber for respective predetermined periods of time corresponding to said kinds of material gases; and
wherein, after a lapse of said predetermined periods of time, switching is made so as to supply said material gases into said chamber from said respective gas sources.

2. A vapor deposition method according to claim 1,
wherein a first gas including a compound containing a tungsten atom and a second gas including a compound containing a silicon atom are used as said one or more kinds of material gases.

3. A vapor deposition method comprising the step of supplying one or more kinds of material gases into a chamber accommodating a substrate therein from one or more gas sources containing said respective material gases, so as to deposit a predetermined compound onto said substrate;
wherein said material gases are supplied from said respective gas sources to the outside of said chamber; and
wherein, after a flow rate of said material gases from said gas sources or a ratio of fluctuation thereof attains a value within a predetermined range, switching is made so as to supply said material gases into said chamber from said respective gas sources.

4. A vapor deposition method according to claim 3,
wherein a first gas including a compound containing a tungsten atom and a second gas including a compound containing a silicon atom are used as said one or more kinds of material gases.

5. A vapor deposition apparatus for depositing a predetermined compound by supplying one or more kinds of material gases onto a substrate, said apparatus comprising:
a chamber for accommodating said substrate;
one or more gas sources including said respective material gases;
one or more gas supply sections, connected to said chamber and said respective gas sources, having respective flow-rate adjusting sections for adjusting flow rates of said material gases;
one or more gas exhaust sections connected between said respective gas flow-rate adjusting sections in said gas supply sections and said chamber; and
one or more blocking sections capable of independently blocking said respective material gases from being supplied to said chamber and said respective gas exhaust sections.

6. A vapor deposition apparatus according to claim 5, further comprising:
a control section, connected to said blocking sections or said flow-path switching sections, for controlling opening/closing of said blocking sections or said switching of said flow paths effected by said respective flow-path switching sections, so as to start supplying said material gases to said chamber after said material gases are supplied from said gas supply sections to said gas exhaust sections for respective predetermined periods of time corresponding to said kinds of material gases.

7. A vapor deposition apparatus according to claim 5, further comprising:
a control section, connected to said flow-rate adjusting sections and said blocking sections or flow-path switching sections, for controlling opening/closing of said blocking sections or said switching of said flow paths, so as to start supplying said material gases to said chamber according to respective flow rate value signals acquired by said flow-rate adjusting sections.

8. A vapor deposition apparatus according to claim 5, wherein said one or more material gases are a first gas including a compound containing a tungsten atom, and a second gas including a compound containing a silicon atom; and
wherein said one or more gas sources are a first gas source having said first gas, and a second gas source having said second gas.

9. A vapor deposition apparatus for depositing a predetermined compound by supplying one or more kinds of material gases onto a substrate, said apparatus comprising:
a chamber for accommodating said substrate;
one or more gas sources including said respective material gases;
one or more gas supply sections, connected to said chamber and said respective gas sources, having respective flow-rate adjusting sections for adjusting flow rates of said material gases;
one or more gas exhaust sections connected between said respective gas flow-rate adjusting sections in said gas supply sections and said chamber; and
one or more flow-path switching sections for switching respective flow paths of said material gases such that said material gases are supplied to one of said chamber and said respective gas exhaust sections.

10. A vapor deposition apparatus according to claim 9, further comprising:
a control section, connected to said blocking sections or said flow-path switching sections, for controlling opening/closing of said blocking sections or said switching of said flow paths effected by said respective flow-path switching sections, so as to start supplying said material gases to said chamber after said material gases are supplied from said gas supply sections to said gas exhaust sections for respective predetermined periods of time corresponding to said kinds of material gases.

11. A vapor deposition apparatus according to claim 9, further comprising:
a control section, connected to said flow-rate adjusting sections and said blocking sections or flow-path switching sections, for controlling opening/closing of said blocking sections or said switching of said flow paths, so as to start supplying said material gases to said chamber according to respective flow rate value signals acquired by said flow-rate adjusting sections.

12. A vapor deposition apparatus according to claim 9, wherein said one or more material gases are a first gas including a compound containing a tungsten atom, and a second gas including a compound containing a silicon atom ; and
wherein said one or more gas sources are a first gas source having said first gas, and a second gas source having said second gas.
